(19) United States
(12) Patent Application Publication
(10) Pub. No.: US 2009/0141334 A1
(43) Pub. Date: Jun. 4, 2009

(54) ELECTRONIC DEVICE HOUSING HAVING TUNABLE METALLIC APPEARANCE

(75) Inventors: Kenneth Dean, Phoenix, AZ (US); Emmett Howard, Gilbert, AZ (US); Scott Johnson, Scottsdale, AZ (US); Dirk Jordan, Gilbert, AZ (US)

Correspondence Address: INGRASSIA FISHER & LORENZ, P.C. (MOT), 7010 E. Cochise Road, SCOTTSDALE, AZ, 85253, US

(73) Assignee: MOTOROLA, INC., Schaumburg, IL (US)

(21) Appl. No.: 11/948,251

(22) Filed: Nov. 30, 2007

(51) Int. Cl. G02B 26/02; H05K 5/04

(52) U.S. Cl. 359/290

(57) ABSTRACT

An electronic device (110, 210) includes a housing (120) encasing a component (112, 114). The housing (120) includes a region (300, 600, 800, 1000) contiguous to the component (112, 114), the region (300, 600, 800, 1000) configured to selectively switch between a metallic appearance to transparent to reveal the component (112, 114) through the region (300, 600, 800, 1000) when transparent. Metal surfaces, metal particles, or shiny particles that are incorporated into device structures may be actuated. The grain sizes of the particles can be adjusted to achieve the desired reflections. In addition, individual shutters (318, 618, 818, 1018) can be fabricated with a distribution of predisposed orientations to enhance the reflectivity.

### FIELD

The present invention generally relates to portable electronic devices and more particularly to a method and apparatus for changing the appearance of the housing thereof.

### BACKGROUND

The market for electronic devices, especially personal portable electronic devices, for example, cell phones, personal digital assistants (PDA's), digital cameras, and music playback devices (MP3), is very competitive. Manufactures are constantly improving their product with each model in an attempt to cut costs and to meet production requirements.

The look and feel of personal portable electronics devices is now a key product differentiator and one of the most significant reasons that consumers choose specific models. From a business standpoint, outstanding designs (form and appearance) may increase market share and margin.

Consumers are enamored with appearance features that reflect personal style. Consumers select them for some of the same reasons that they select clothing styles, clothing colors, and fashion accessories. Plastic snap-on covers for devices such as cell phones and MP3 players can be purchased in pre-defined patterns and colors. These snap-on covers are quite popular, and yet they provide a limited customization capability.

Known electronic devices have touch keypads, displays, function buttons and the like that appear through the housing, which alter the appearance of the housing. Furthermore, the consumer may desire to prevent the display, for example, from appearing until desired. Know methods for implementing this look include providing emissive technology such as light emitting diodes under translucent plastic or dark glass. Emissive technology requires a lot of power, and when shining through materials, requires even more power. This is a detriment to battery life. In some cases a shutter technology, like a twisted nematic liquid crystal, is used to hide displays or buttons.

Many portable electronic devices have been made with metallic looking surfaces, which have great appeal to consumers. The Motorola RAZR cell phone, for example, has a magnesium housing. However, it is very difficult to provide a uniform metallic look over the entire phone surface. In a commercially available example, a thin semi-transparent gold coating is deposited on the protective transparent material overlying the LCD display. The surface looks gold until the LCD backlight is activated. Then a fraction of the LCD light penetrates the semitransparent coating to reveal the display. This scheme is inefficient with power, but more importantly, since the reflective surface is still present, the contrast of the emissive display is poor under bright lighting conditions encountered outdoors.

Accordingly, it is desirable to provide an electronic device housing having a tunable metallic appearance. Furthermore, other desirable features and characteristics of the present invention will become apparent from the subsequent detailed description and the appended claims, taken in conjunction with the accompanying drawings and this background.

### BRIEF DESCRIPTION OF THE DRAWINGS

Embodiments of the present invention will hereinafter be described in conjunction with the following drawing figures, wherein like numerals denote like elements, and

FIG. 1 is an isometric view of a portable electronic device in accordance with an exemplary embodiment;

FIG. 2 is a block diagram of a portable electronic device in accordance with an exemplary embodiment;

FIG. 3 is a partial cross section of a first exemplary embodiment of an electro wetting device without a voltage applied;

FIG. 4 is a partial cross section of the first exemplary embodiment with a voltage applied;

FIG. 5 is an isometric view of the first exemplary embodiment without a voltage applied.

FIG. 6 is a partial cross section of a second exemplary embodiment of an electro wetting device without a voltage applied;

FIG. 7 is a partial cross section of the second exemplary embodiment with a voltage applied;

FIG. 8 is a partial cross section of a third exemplary embodiment without a voltage applied;

FIG. 9 is a partial cross section of the third exemplary embodiment with a voltage applied;

FIG. 10 is a partial cross section of a fourth exemplary embodiment without a voltage applied; and

FIG. 11 is a partial cross section of the fourth exemplary embodiment with a voltage applied.

### DETAILED DESCRIPTION

Many consumers like their electronic devices to have a metallic appearance. A metallic appearance is more than just a color. Yellow-orange does not provide the look of gold, nor does gray represent stainless steel. Metals look the way they do for several reasons. First, the electronic structure of metal reflects a substantial percentage of the incident light, as much as 90%, which is much greater than most other non-metal surfaces. Typical metal surfaces are smooth enough to demonstrate significant specular reflection, rather than diffuse reflection. As a result, a metal's reflective brightness varies with the surface's angle to the light source. This gives metal its characteristic angularly-dependent brightness which varies with the relative orientations of a viewer and a light source. In addition, reflection off metal surfaces is also often polarized. Metals also have grain structures which can act of a collection of small specular reflectors with a distribution of reflecting angles. This can produce a highly reflective, but granular, texture that still maintains a large angularly dependent reflection. Some decorative metals reflect light more efficiently in the yellow and red regions of the spectrum than in the blue and green regions, providing gold and copper colors. A metallic appearance is defined as a surface exhibiting bright, predominantly specular reflections, wherein the reflections vary with the angle of the light source and are a function of the material and the granular characteristics of the surface. For this reason, computer graphics experts have a difficult time creating metal-looking objects. It is difficult to use reflective shutter technology that is known in the art to create a metallic-looking surface. For example, shutters made from liquid crystals, cholesteric liquid crystals, and electrochromic materials, will not look metallic. Note that electrophoretic technology (provided by the company E-ink) does not have a transparent state and will not operate as a shutter. Metallic looking paints incorporate reflective additives, such as metal flakes and mica flakes to create the enhanced shiny look, but the additives are not actively-controllable.

The exemplary embodiments described herein include several technologies wherein incorporated metal surfaces, metal particles, or shiny particles into device structures may be actuated. The grain sizes of the particles can be adjusted to achieve the desired reflections.

An electronics device is described having a housing, or a region of a housing, that maintains a metallic appearance when not in use, but which transforms into a transparent housing, or region, when desired to reveal device functional elements, such as a display or a touch screen, within the portable electronics device. This transformation is accomplished by providing a surface with metal shutters that can be physically moved on application of a stimulus. A common stimulus would be an electrical signal, but other stimuli are possible. The stimulus may be triggered when the electronic device receives an RF signal or when the user takes a particular action.

The exemplary embodiments teach a surface containing metallic shutters. In many embodiments, a microelectromechanical system (MEMS) including an array of pixels can provide optical switching. In an embodiment utilizing typical solid MEMs, the housing is fabricated as a mirror array using rollable metal strips. When planar, the metal strips present a unified metallic appearance, but when each of the metal strips are rolled to the side, the housing is transparent revealing the element or elements below. Other embodiments employ a liquid form of MEMs using electrowetting or electrocapilliary responses. In one exemplary embodiment, a liquid metal alloy, such as Galinstan®, is modulated through a electrowetting effect, being displaced like a shutter. Galinstan, a registered trademark of Geratherm Medical, provides a highly metallic looking appearance, while the electrowetting technology provides aperture when activated to display the underlying elements. Galinstan is a eutectic alloy of gallium, indium, and tin which is liquid at room temperature (typically freezing at −20° C. (−4° F.)), beads up on hydrophobic surfaces, and has a high reflectivity. Another embodiment includes passivated reflectivel flakes, for example, disposed between a polar liquid and a non-polar liquid, which are modulated in an electrowetting manner. Alternatively, a non-polar fluid (i.e. oil or alkane) is combined with the reflective flakes that are passivated with an insulating oleophilic layer. It should be noted that the surface containing the metallic shutters often includes a bottom substrate and top substrate, with the shutters in between. The substrates provide both a vehicle for electrical contact, and protection from the environment.

The following detailed description is merely exemplary in nature and is not intended to limit the invention or the application and uses of the invention. Furthermore, there is no intention to be bound by any theory presented in the preceding background or the following detailed description.

FIG. 1 shows in schematic form a mobile communication device, which may be used with the exemplary embodiments of a portable electronic device 110 described herein, and includes a display 112, a control panel 114, a speaker 116, and a microphone 118 formed within a housing 120. Conventional mobile communication devices also include, for example, an antenna and other inputs which are omitted from the figure for simplicity. Circuitry (not shown) is coupled to each of the display 112, control panel 114, speaker 116, and microphone 118. It is also noted that the portable electronic device 110 may comprise a variety of form factors, for example, a “foldable” cell phone. While this embodiment is a portable mobile communication device, the present invention may be incorporated within any electronic device having elements to be viewed through the housing by the consumer. Other portable applications include, for example, a laptop computer, personal digital assistant (PDA), digital camera, or a music playback device (e.g., MP3 player). Non-portable applications include, for example, car radios, stainless steel refrigerators, watches, and stereo systems. The low power requirements of the MEMS and electrowetting structures presented here make them particularly well suited to portable electronics devices. Typically, they consume less than 1 microwatt per centimeter squared of device area. They can cover entire surfaces of most portable electronic devices in full actuation, without draining significant battery power between charges.

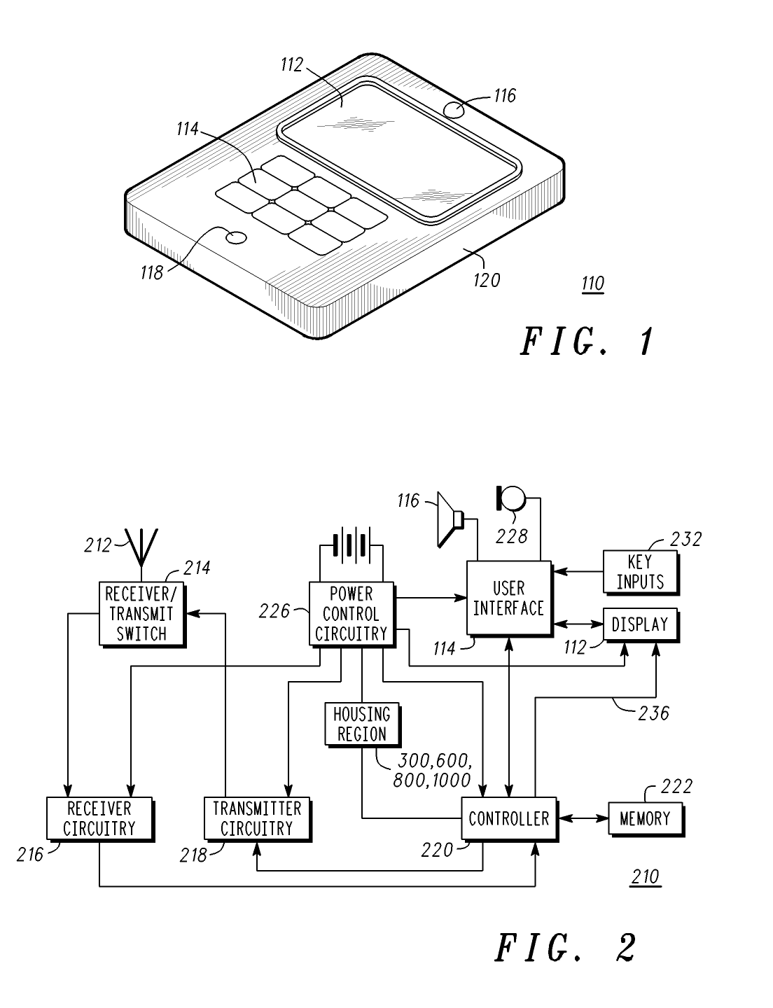

Referring to FIG. 2, a block diagram of a portable electronic device 210 such as a cellular phone, in accordance with the exemplary embodiment is depicted. Though the exemplary embodiment is a cellular phone, the invention described herein may be used with any electronic device in which information is to be presented. The portable electronic device 210 includes an antenna 212 for receiving and transmitting radio frequency (RF) signals. A receive/transmit switch 214 selectively couples the antenna 212 to receiver circuitry 216 and transmitter circuitry 218 in a manner familiar to those skilled in the art. The receiver circuitry 216 demodulates and decodes the RF signals to derive information therefrom and is coupled to a controller 220 for providing the decoded information thereto for utilization thereby in accordance with the function(s) of the portable communication device 210. The controller 220 also provides information to the transmitter circuitry 218 for encoding and modulating information into RF signals for transmission from the antenna 212. As is well-known in the art, the controller 220 is typically coupled to a memory device 222 and a user interface 114 to perform the functions of the portable electronic device 210. Power control circuitry 226 is coupled to the components of the portable communication device 210, such as the controller 220, the receiver circuitry 216, the transmitter circuitry 218 and/or the user interface 114, to provide appropriate operational voltage and current to those components. The user interface 114 includes a microphone 228, a speaker 116 and one or more key inputs 232, including a keypad. The user interface 114 may also include a display 112 which could include touch screen inputs. The display 112 is coupled to the controller 220 by the conductor 236 for selective application of voltages in some of the exemplary embodiments described below.

The exemplary embodiments described herein may be fabricated using known lithographic processes as follows. The fabrication of integrated circuits, microelectronic devices, micro electro mechanical devices, microfluidic devices, and photonic devices, involves the creation of several layers of materials that interact in some fashion. One or more of these layers may be patterned so various regions of the layer have different electrical or other characteristics, which may be interconnected within the layer or to other layers to create electrical components and circuits. These regions may be created by selectively introducing or removing various materials. The patterns that define such regions are often created by lithographic processes. For example, a layer of photoresist material is applied onto a layer overlying a wafer substrate. A photomask (containing clear and opaque areas) is used to selectively expose this photoresist material by a form of radiation, such as ultraviolet light, electrons, or x-rays. Either the photoresist material exposed to the radiation, or that not exposed to the radiation, is removed by the application of a developer. An etch may then be applied to the layer not protected by the remaining resist, and when the resist is removed, the layer overlying the substrate is patterned. Alternatively, an additive process could also be used, e.g., building a structure using the photoresist as a template.

Though the above described lithography processes are preferred, other fabrication processes may comprise any form of lithography, for example, ink jet printing, photolithography, electron beam lithography, and imprint lithography ink jet printing. In the ink jet printing process, pigments or metal flakes may be combined in liquid form with the oil and printed in desired locations on the substrate.

A low cost reflective display technology, electrowetting light valves, may be used to produce stacked black and white shutters, colored shutters, or reflective shutters, as described herein, over a surface. Typical electrowetting devices use a low frequency voltage, including DC, to change the wetting properties of a polar fluid (water) on a hydrophobic surface. When devices incorporate a colored oil layer on the hydrophobic surface, electrical actuation moves the polar fluid to the hydrophobic layer, thereby moving the colored oil like a shutter in and out of view. The ‘open’ condition of the shutter is transparent (not black or white) so that the underlying features are visible when the oil is out of view.

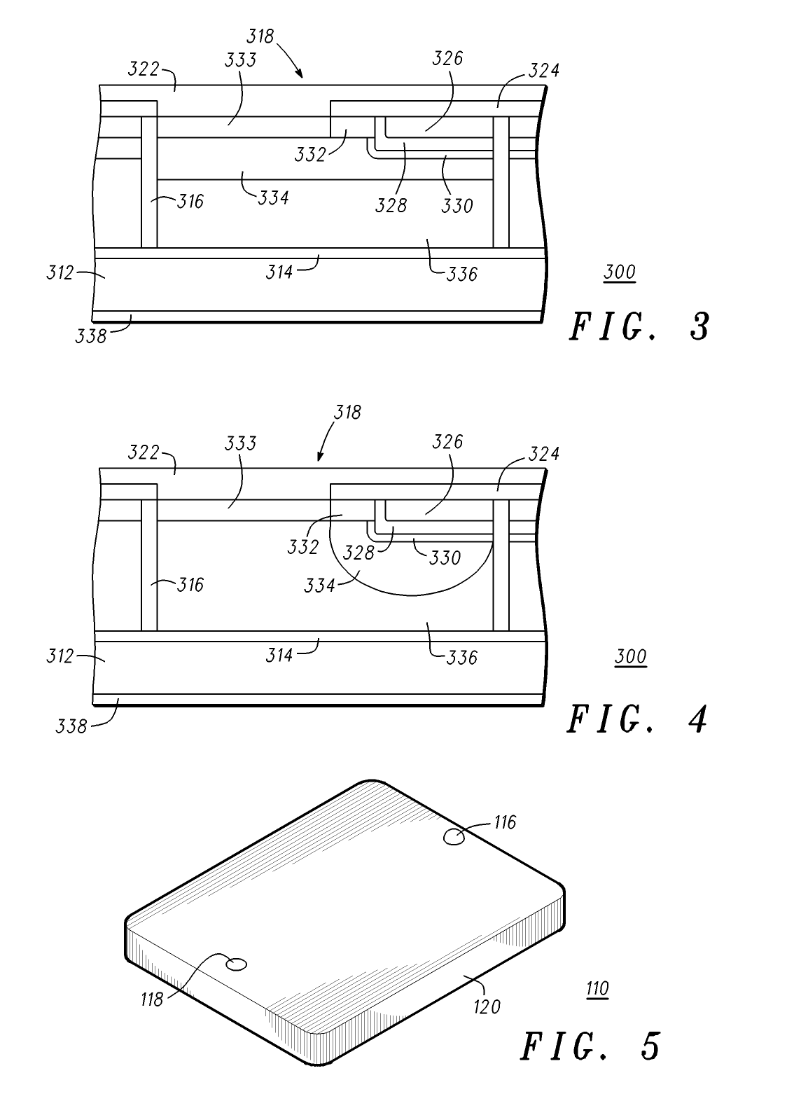

FIG. 3 is a partial cross section of a electrowetting display 300 of a single pixel, in accordance with the exemplary embodiment, comprising an optional transparent dielectric layer 314 deposited on a transparent substrate 312. Adjacent spacers 316 of a plurality of spacers define a pixel 318 of a plurality of pixels. A top transparent substrate 322 overlies the spacers 316 and has a stack of layers attached thereto and disposed contiguous to a spacer 316, including an opaque layer 324, an electrode 326, a hydrophobic layer 333, a dielectric layer 328, and a hydrophobic layer 330. An electrode 332 and a liquid metal 334 are positioned between the stack of layers and another spacer 316. The electrode 332 comprises, for example, indium tin oxide, and the liquid metal 334 comprises a metal having a metallic appearance, for example, Galinstan in electrical contact. Hydrophobic layer 330, comprising fluorinated materials such as Dupont Teflon AF® is substantially more hydrophobic than layer 333 which comprises materials such as parylene. An inert, transparent gas or oil 336 is filled within a cavity formed between the spacers 316. When no voltage is applied across the electrodes 326 and 332, the liquid metal 334 assumes the position in the optical path as shown, giving a metal appearance to the housing. The close coupling of the liquid metal and the optical surface produces a very shiny reflection. The color of the reflective metal can be adjusted to gold or copper tones with a filter. The color of underlying components could also be adjusted for the filter. For example, the white point of an emissive liquid crystal display might be adjusted to emit more yellow.

FIG. 4 is the exemplary embodiment of FIG. 3 with a voltage, e.g., a DC/low frequency voltage to 200 hertz but preferably less than 40 volts, applied between the electrodes 326 and 332, the liquid metal 334 moves to the side as shown, under the opaque layer 324. The area vacated by the liquid metal 334 is now transparent, revealing the element directly beneath. Transparency of the housing 120 is maintained by continual application of the voltage. However, the leakage current is tremendously small. For the cases where the power requirements are important, transparency can be maintained for minutes and hours without significantly depleting the rechargeable battery of a typical portable electronic device. Another low power driving approach make use of the fact that transparency can be maintained for minutes after the voltage source (not shown) is disconnected. In the illustrated structure, voltage levels are applied to the pixel 300 once to set the desired transparency, and then they are re-applied at intervals (for example, 2 minutes), to refresh the charge.

FIG. 5 is the electronic device 110 of FIG. 1 wherein the liquid metal 334 dispersed across the pixels 318 giving the entire housing a metallic appearance. FIG. 1 illustrates the liquid metal 334 having been moved to the side of the pixels 318, revealing the screen 112 and touchscreen 114 therebeneath.

Though the transition from metallic appearance to transparency and back, may be accomplished at various trigger points, it is anticipated the metallic appearance would be maintained (by disconnecting the voltage) when the portable electronic device 110 is not in use. When some action occurs, the voltage is applied and the housing becomes transparent, revealing one or more electronic elements within the housing. Examples of the electronic elements include a display 112, a touch screen 114, printed circuit board including numerous transistors, resistors, and the like making up the circuitry 216, 218, 220, 222, 226, and the key inputs 232. Examples of actions prompting the housing 120 to become transparent include an RF signal being received, a button being touched or pushed by the user, or a change detected by a proximity or motion detector.

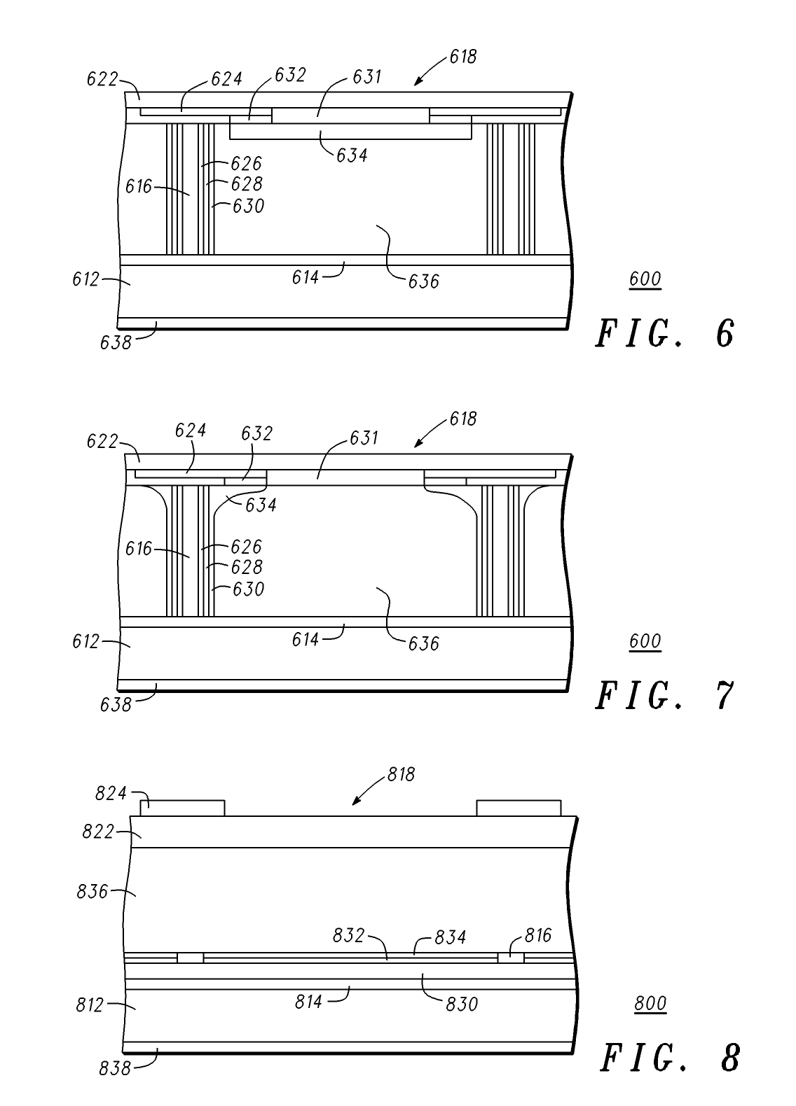

FIGS. 6 and 7 illustrate another exemplary embodiment similar to that of FIGS. 3 and 4, wherein a partial cross section of an electrowetting display 600 of a single pixel, in accordance with the exemplary embodiment, comprising an optional transparent dielectric layer 614 deposited on a transparent substrate 612. Adjacent spacers 616 of a plurality of spacers define a pixel 618 of a plurality of pixels. A top transparent substrate 622 overlies the spacers 616 and has an opaque layer 624 disposed between the substrate 622 and the spacers 616, and electrodes 632 disposed under the opaque layer at the edges of the cells. Layer 631 is a hydrophobic dielectric disposed on the bottom surface of substrate 612. An electrode 626, a dielectric layer 628, and a hydrophobic layer 630 are disposed contiguous to the spacer. A transparent electrode 632 and liquid metal 634 are positioned between the opaque layers 624. The electrodes 632 comprises, for example, indium tin oxide, and the liquid metal 634 comprises a metal having a metallic appearance, for example, Galinstan in electrical contact with electrodes 632. Hydrophobic layer 630, comprising fluorinated materials such as Dupont Teflon AF® is substantially more hydrophobic than layer 631 which comprises materials such as parylene. An inert, transparent gas or a non-polar fluid (oil) 636 is filled within a cavity formed between the spacers 616. When no voltage is applied between the electrodes 626 and 632, the liquid metal 634 assumes the position in the optical path as shown, giving a metal appearance to the housing.

FIG. 7 is the exemplary embodiment of FIG. 6 with a voltage, e.g., a DC/low frequency voltage to 200 hertz, but preferably less than 40 volts, applied between the electrodes 626 and 632, the liquid metal 634 moves to the side as shown, under the opaque layer 624. The area vacated by the liquid metal 634 is now transparent, revealing the element 638 directly beneath. Transparency of the housing 120 is maintained by continual application of the voltage. However, the leakage current is tremendously small, and transparency can be maintained for minutes after the voltage source (not shown) is disconnected. In the illustrated structure, voltage levels are applied to the pixel 300 once to set the desired transparency, and then they are re-applied at intervals (for example, 2 minutes), to refresh the charge.

Referring to FIG. 8, another exemplary embodiment is shown as a partial cross section of a display 800 of a single pixel, comprising an optional transparent dielectric layer 814 deposited on a transparent substrate 812. Adjacent spacers 816 of a plurality of spacers define a pixel 818 of a plurality of pixels including a transparent hydrophobic dielectric layer 830, and a transparent electrode 814 disposed between the spacers and the substrate 812. A plurality of reflective flakes 834 is disposed between the non-polar fluid 832 and the polar fluid 836. In one embodiment, the flakes are maintained at the interface because they have a density between that of the polar and non-polar fluids. In another embodiment, the flakes are fabricated with one side having a surface which is attracted to the polar fluid more than the non-polar fluid, and the other side which is attracted to the non-polar fluid more than the polar fluid. Surfaces which are hydrophilic and oleophobic, or hydrophobic and oleophilic are examples for how to manage the preferences preferential positioning of the flakes. The suspension of the flakes between the fluids helps alignment.

The transparent electrode 814 comprises, for example, indium tin oxide or PEDOT:PSS, and the reflective flakes 834 can be selected from materials such as metals like aluminum and copper, aluminized mylar, metallized plastics, mica, titania-coated mica, and diffraction grating materials. For optimal reflection, the thickness of the flakes must be sufficient to eliminate light transmission. For metallized films, this thickness is typically in the range of 100 to 300 nm as a minimum. For a metallic-looking surface, there is an optimal range for the overall size of the metal flakes (length and width). First, the size of a single pixel must be small enough that the pixelization does not attract the viewer's attention. Typically, this size is less than 500×500 micrometers, and preferably less than 350×350 micrometers. Note that the pixels may take any shape. Individual flakes must be considerably smaller than the pixel size so that the flakes do not alter the basic electrowetting behavior of the cell. Flakes that are 1/10^{th} the area of the pixel and smaller produce good electrowetting response. However, flakes must be large enough that they create a metallic optical response, so typically they are larger than 1 micrometer. Matching the size of the flakes to the grain size of metal surface is a convenient way to select an optimal flake size.

The polar fluid is electrically connected to another electrode on the periphery of the device (not shown). An opaque material 824 overlies a portion of the substrate 822 to “hide” the spacers 816 and reflective flakes 834. When no voltage is applied across the electrodes 814, the reflective flakes 834 assume the position in the optical path as shown, giving a metal appearance to the housing. In another embodiment, the reflective flakes might be incorporated into the non-polar fluid as a mixture. In other embodiments (not shown), the reflective flakes could also be embedded into a polar fluid. Such a system would be an air-polar fluid system. The color of the reflective flakes may be modified by dyes in the polar or non-polar liquids, or filters over the surface. In this way, aluminum flakes can produce a copper or gold appearance. In some cases, the color of the underlying components may need to be adjusted to compensate for the color filter.

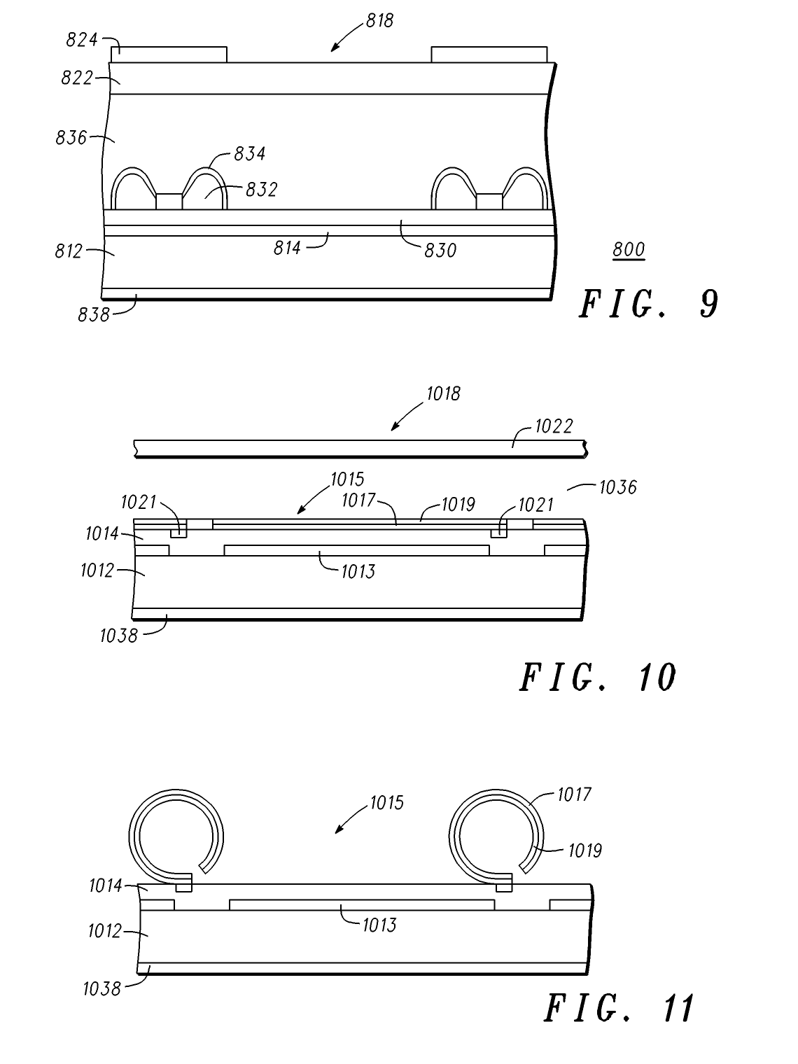

FIG. 9 is the exemplary embodiment of FIG. 8 with a voltage, e.g., a DC/low frequency voltage to 200 hertz but preferably less than 40 volts, applied between the electrodes 814 and a peripheral electrode (not shown) connected to the polar fluid, the reflective flakes 834 moves to the side as shown, under the opaque layer 824. The area vacated by the reflective flakes 834 is now transparent, revealing the element directly beneath. Transparency of the housing 120 (FIG. 1) is maintained by continual application of the voltage. However, the leakage current is tremendously small, and transparency can be maintained for minutes after the voltage source (not shown) is disconnected. In the illustrated structure, voltage levels are applied to the pixel 800 once to set the desired transparency, and then they are re-applied at intervals (for example, 2 minutes), to refresh the charge.

FIG. 10 is a partial cross section of a display 1000 of a single pixel, in accordance with the exemplary embodiment, comprising a transparent conductor 1013, and a transparent dielectric layer 1014 deposited on a transparent substrate 1012. A top transparent substrate 1022 is displaced above the transparent dielectric layer 1014 by spacers (not shown), thereby providing a cavity 1036. A conductive strip 1015, defining a pixel 1018, is formed on the transparent dielectric layer 1014 and coupled at one end to a conductive region 1021. The transparent dielectric layer comprises, for example, silicon dioxide or silicon nitride, and the conductive strip 1015 includes a first compressive layer 1017 and a second tensile layer 1019, both comprising a metal, preferably tungsten. When no voltage is applied to the conductive region 1021, the conductive strip 1015 assumes the position in the optical path as shown in FIG. 10, giving a metal appearance to the housing.

FIG. 11 is the exemplary embodiment of FIG. 10 with a voltage, e.g., a DC/low frequency voltage to 200 hertz but preferably less than 40 volts, applied to the conductive region 1021, the conductive strip 1015 rolls to the side as shown. Additional material forming ribs (not shown) may be applied to the conductive strip to provide lateral stiffness to prevent curling along the axis. A detailed description of such rollable conductive strips may be found in U.S. Pat. Nos. 3,989,357 and 5,233,459. The area vacated by the conductive strip 1015 is now transparent, revealing the underlying element 1038 directly beneath. Transparency of the housing 120 is maintained by continual application of the voltage. In exemplary embodiments incorporating a bistable shape, no voltage would be required to maintain an open state.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. An electronic device comprising:
a component; and
a housing encasing the component and comprising a region contiguous to the component, the region configured to selectively switch between a metallic appearance to transparent to reveal the component through the region when transparent.

2. The electronic device of claim 1 wherein the region comprises an electrowetting structure including a metallic metal alloy.

3. The electronic device of claim 1 wherein the region comprises a plurality of rollable metal strips.

4. The electronic device of claim 1 wherein the region comprises an electrowetting structure including a plurality of reflective flakes.

5. The electronic device of claim 1 wherein the components include a display screen made visible through the region when transparent.

6. The electronic device of claim 1 wherein the components include touch buttons made visible through the region when transparent.

7. The electronic device of claim 1 wherein the components include a camera lens made visible through the region when transparent.

8. An electronic device, comprising:
a housing capable of alternatingly assuming a metallic or transparent appearance, comprising:
a plurality of layers defining a plurality of pixels; and
a reflective material disposed within each of the pixels;
a component disposed within the housing; and
circuitry disposed within the housing and configured to selectively reposition the reflective material, wherein the component is visible through the housing when the housing is transparent.

9. The electronic device of claim 8 wherein the plurality of layers comprises an electrowetting structure and the reflective material comprises a metallic metal alloy.

10. The electronic device of claim 8 wherein the reflective material comprise a plurality of rollable metal strips.

11. The electronic device of claim 8 wherein the plurality of layers comprises an electrowetting structure and the reflective material comprises a plurality of reflective flakes.

12. The electronic device of claim 8 wherein the components include a display screen made visible through the housing when transparent.

13. The electronic device of claim 8 wherein the components include touch buttons made visible through the housing when transparent.

14. The electronic device of claim 8 wherein the components include a camera lens made visible through the housing when transparent.

15. A method for changing the appearance of a housing of an electronic device, comprising:
selectively enabling and disabling and a voltage between first and second electrodes to reposition a reflective material for alternating between transparency and a metallic appearance for a region of the housing of the electronic device.

16. The electronic device of claim 15 wherein the selectively enabling and disabling step comprises selectively enabling and disabling an electrowetting structure including a metallic metal alloy.

17. The electronic device of claim 15 wherein the selectively enabling and disabling step comprises selectively enabling and disabling a plurality of rollable metal strips.

18. The electronic device of claim 15 wherein the selectively enabling and disabling step comprises selectively enabling and disabling an electrowetting structure including a plurality of reflective flakes.

19. The electronic device of claim 15 wherein the selectively enabling and disabling step comprises displaying a display screen when the region is transparent.

20. The electronic device of claim 15 wherein the selectively enabling and disabling step comprises displaying touch buttons when the region is transparent.

21. The electronic device of claim 15 wherein the selectively enabling and disabling step comprises displaying a camera lens when the region is transparent.
